(19) United States
(12) Patent Application Publication
(10) Pub. No.: US 2001/0022370 A1
(43) Pub. Date: Sep. 20, 2001

(54) Transducer module with an optical semiconductor, and method for producing a transducer module

(76) Inventor: Frank Meyer-Guldner, Berlin (DE)

Correspondence Address: LERNER AND GREENBERG, P.A., Post Office Box 2480, Hollywood, FL, 33022-2480, US

(21) Appl. No.: 09/740,651

(22) Filed: Dec. 18, 2000

(30) Foreign Application Priority Data
Dec. 17, 1999 (DE) 199 63 262.6

(51) Int. Cl. H01L 21/00; H01L 27/148; H01L 29/768

(52) U.S. Cl. 257/225; 438/48

(57) ABSTRACT

A transducer module for transmitting and/or receiving light has at least one optical semiconductor which is electrically connected to contacts which are provided on a bottom side of a baseplate. The at least one optical semiconductor is provided such that the light can be transmitted in a transmitting direction away from a top side of the baseplate, and that the light can be received in a receiving direction toward the top side of the baseplate. The contacts are provided through the use of conductor tracks which are electrically insulated from the baseplate and are constructed on a printed circuit board substrate. A method for producing a transducer module is also provided.

### BACKGROUND OF THE INVENTION

1. Field of the Invention

The invention relates to a transducer module for transmitting and/or receiving light with at least one optical semiconductor which is electrically connected to contacts which are formed on a bottom side of a baseplate. The at least one optical semiconductor is provided in such a way that the light can be transmitted in a transmitting direction away from a top side of the baseplate, and that the light can be received in a receiving direction toward the top side of the baseplate. The invention also relates to a method for producing such transducer modules.

Transducer modules of this type are used in the field of optical waveguide technology for an electrooptic and/or optoelectric conversion of light signals or optical signals. Such applications of transducer modules require a high integration density of the transducer module.

### SUMMARY OF THE INVENTION

It is accordingly an object of the invention to provide a transducer module which has an improved integration density of the components of the transducer module. It is a further object of the invention to provide a suitable method for producing such a transducer module.

With the foregoing and other objects in view there is provided, in accordance with the invention, a transducer module for transmitting and/or receiving light, including:

a baseplate having a top side and a bottom side;

a printed circuit board substrate disposed on the bottom side of the baseplate;

conductor tracks provided on the printed circuit board substrate and being electrically insulated from the baseplate; and

at least one optical semiconductor electrically connected to the conductor tracks, the at least one optical semiconductor being positioned such that light is at least one of receivable and transmittable in a respective direction toward and away from the top side of the baseplate.

In other words, the object of the invention is achieved by the virtue of the fact that the contacts to be connected to the optical semiconductor are provided with the aid of conductor tracks which are electrically insulated from the baseplate and which are constructed on a printed circuit board substrate.

The essential advantage of the invention over the prior art is that the contacts required for connecting the optical semiconductor are constructed on a printed circuit board substrate which can be fabricated cost-effectively. Moreover, the configuration of the conductor tracks on the printed circuit board substrate permits a high integration and packing density of the transducer module, in particular because several conductor track layers can be formed and provided one above another.

Moreover, the construction of the contacts or conductor tracks separate from the baseplate permits a flexible configuration of the transducer module, since it is possible to provide on the baseplate different contact configurations which are adapted to different applications. Moreover, by contrast with known transducer modules in which the lead frame technique is used to construct contacts, there is the advantage that it is possible to provide standardized EMC (electromagnetic compatibility) protection with little outlay.

A preferred embodiment of the invention provides that the conductor tracks are electrically insulated from the baseplate with the aid of an insulating adhesive, as a result of which, firstly, the conductor tracks are insulated in a simple way. Secondly, the conductor tracks are fixed on the bottom side of the baseplate with the aid of the adhesive.

According to another feature of the invention, the conductor tracks are expediently electrically insulated from the baseplate with the aid of the printed circuit board substrate, thus dispensing with an otherwise required separate insulating layer independent of the printed circuit board substrate.

According to yet another feature of the invention, the printed circuit board substrate is formed from polyimide which results in a cost-effective printed circuit board substrate which can be processed with little outlay.

According to another feature of the invention, it may be provided that the at least one optical semiconductor is connected to the conductor tracks with the aid of bonds, in particular wire or tape bonds. As a result the electrical connection of the at least one optical semiconductor can be carried out with the aid of techniques which are known per se.

The at least one optical semiconductor and the bonds are advantageously surrounded at least partially by a casting compound, thus insulating these members and providing protection against external influences.

One expedient embodiment of the invention provides that the baseplate is configured as a heat sink, thus ensuring the thermal dissipation required in the case of the high integration density of the transducer module.

The baseplate is advantageously made from a metal, such as copper, thus ensuring effective shielding against electromagnetic interference fields.

According to another feature of the invention, a passage is formed in the baseplate, a light path running at least partially through the passage during transmission and/or reception of the light. As a result, a transmitting and/or receiving surface of the at least one optical semiconductor is provided at a spacing from the top side of the baseplate such that the region of the baseplate around the passage forms a protective configuration for the transmitting and/or receiving surface of the at least one optical semiconductor.

It is advantageous to provide a lens in the light path in the passage. As a result, the beam path of the transmitted and/or the received light can be influenced.

The lens is expediently configured as a spherical lens, thereby facilitating the mounting of the lens.

In order to permit the lens to be adequately fastened in the passage, it can be provided that the lens is pressed into the passage, or is bonded in the passage through the use of an adhesive, preferably through the use of an index-matched, transparent adhesive.

According to another feature of the invention, the lens projects over a mounting surface on the bottom side of the baseplate such that it is possible with the aid of an etched trench, which is formed on the surface of the at least one optical semiconductor that faces the mounting surface, to carry out a self-adjustment of the optical semiconductor when the optical semiconductor is provided on the mounting surface. This simplifies the adjustment of the optical semiconductor when producing the transducer module.

The lens can advantageously be configured as a silicon lens. This allows to guide the beams of the emitted and/or received light as necessary with the aid of a section of the at least one optical semiconductor.

According to another feature of the invention, the at least one optical semiconductor is provided in a depression on the bottom side of the baseplate. This protects the at least one optical semiconductor by virtue of the fact that it is surrounded by the walls of the depression. A spacing between the walls and the optical semiconductor must be sufficient to ensure that no contact is produced between the walls and the optical semiconductor. Moreover, the configuration of the at least one optical semiconductor in the depression permits an enlargement of contact surfaces in which the surface of the optical semiconductor and the mounting surface touch, thus improving the heat dissipation.

In an advantageous embodiment of the invention, semiconductor components are provided on the bottom side. The semiconductor components are connected to the conductor tracks through the use of further bonds and are thereby electrically connected to the at least one optical semiconductor, thus increasing the integration density, since further semiconductor components can be provided in the immediate vicinity of the at least one optical semiconductor if they are required for the functioning of the transducer module.

According to a further feature of the invention, further depressions for holding the semiconductor components are formed on the bottom side, thus facilitating the positioning of the semiconductor components when mounting the transducer module.

According to yet a further feature of the invention, the conductor tracks are electrically connected to soldering globules such that the transducer module can be soldered on a circuit board with the aid of the soldering globules. As a result, a soldering technique known per se can be used to connect the transducer module to further assemblies.

According to another feature of the invention, a guide member is provided on the top side of the baseplate, above the at least one optical semiconductor, for holding a glass fiber cable or an optical waveguide plug, thus permitting a direct coupling of light between the at least one optical semiconductor and the glass fiber cable or the optical waveguide plug.

According to a further feature of the invention, the guide member has a projection for a self-adjustment of the guide member with regard to the light transmitted or received by the at least one optical semiconductor. This ensures an adjustment of the guide member in a mechanically simple way.

The projection is advantageously provided at least partially in the passage. As a result, the existing passage can be used to hold the projection in such a way that no additional counterpart to the projection needs to be constructed.

With the objects of the invention in view there is also provided, a method for producing a transducer module for transmitting and/or receiving light with at least one optical semiconductor, the method includes the steps of:

applying a contact layer, formed on a printed circuit board substrate, on a bottom side of a baseplate, the contact layer having conductor tracks electrically insulated from the baseplate;

forming at least one cutout in the contact layer;

positioning at least one optical semiconductor in the at least one cutout such that light is receivable and/or transmittable in a respective direction toward and away from a top side of the baseplate;

forming bond connections between the at least one optical semiconductor and the conductor tracks; and

casting the at least one optical semiconductor and the bond connections with a casting compound.

According to another mode of the invention, a passage is formed in the baseplate prior to or subsequent to the positioning step such that at least part of the light is transmittable and/or receivable through the passage. Additionally, a lens is inserted into the passage.

Other features which are considered as characteristic for the invention are set forth in the appended claims.

Although the invention is illustrated and described herein as embodied in a transducer module with an optical semiconductor and a method for producing such a transducer module, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 is a diagrammatic sectional view of a transducer module according to the invention with a lens;

FIG. 2a is a diagrammatic sectional view of a transducer module according to the invention with a silicon lens;

FIG. 2b is a diagrammatic sectional view of a detail of the transducer module with the silicon lens shown in FIG. 2a; and

FIG. 3 is a diagrammatic sectional view of a further embodiment of a transducer module according to the invention.

### DESCRIPTION OF THE PREFERRED EMBODIMENTS

Referring now to the figures of the drawings in detail and first, particularly, to FIG. 1 thereof, there is shown, a transducer module 1 with a polyimide film 4 with conductor tracks 5 provided on a bottom side 2 of a baseplate 3. The polyimide film 4 is a conventional substrate for printed circuit boards.

The baseplate 3 is formed from a punched or an etched plate. The conductor tracks 5 are electrically insulated from the baseplate 3 with the aid of an adhesive layer 6. The baseplate 3 has on its bottom side 2 a depression 7 and a further depression 8. An optical semiconductor 9 is provided in the depression 7 such that light can be transmitted in a transmitting direction away from a top side 10 of the baseplate 3. This is shown in FIG. 1 by way of example with an arrow A. The optical semiconductor 9 can receive light in a receiving direction toward the top side 10 of the baseplate 3. This is illustrated by way of example with an arrow B in FIG. 1.

The light path of the transmitted or received light runs at least partially through a passage 11 which is formed in the baseplate 3. A lens 12, which can be configured as a spherical lens, is provided in the passage 11 in order to influence the beam path of the light emitted by the optical semiconductor 9 or received by the optical semiconductor 9. The lens 12 can be formed from glass or plastic.

In accordance with FIG. 1, the lens 12 is provided in an etched trench 13 which is formed on the optical semiconductor 9. It is possible thereby to adjust the optical semiconductor 9 with regard to the lens 12. The lens 12 is preferably pressed into the passage 11 and/or bonded through the use of an index-matched, transparent adhesive 43.

The use of the lens 12 is also possible, independently of the described mounting configuration in transducer modules in which the optical semiconductor 9 is mounted, for example with the aid of the lead-frame technique.

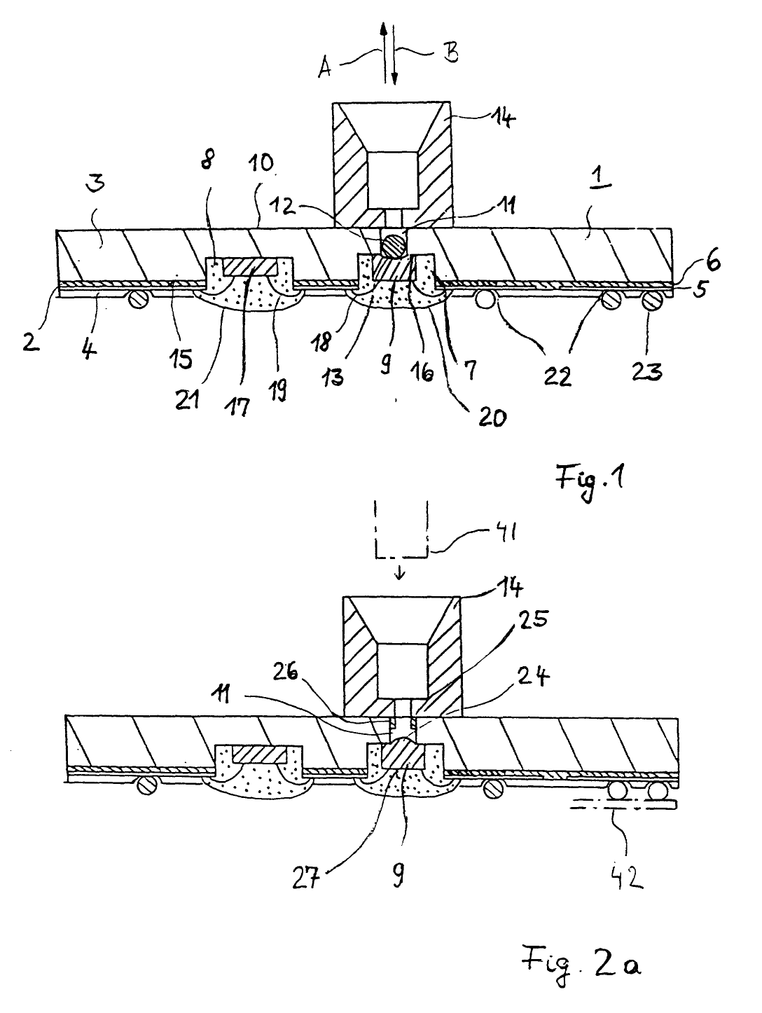

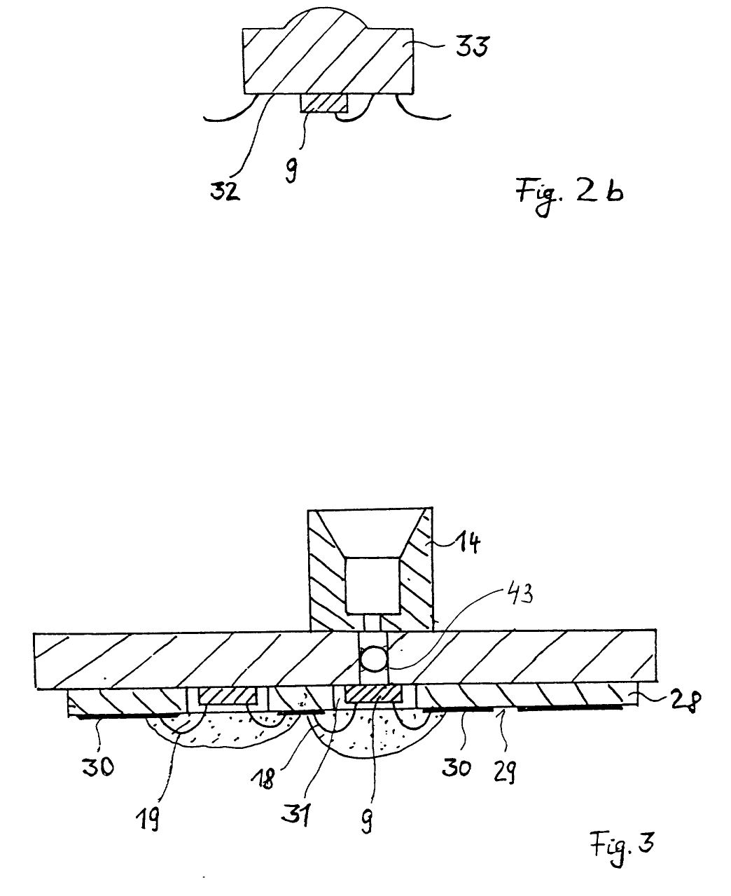

A guide member 14 is provided on the top side 10 of the baseplate 3 in the region of the passage 11. The guide member 14 can hold a component 41, such as a glass fiber cable or an optical waveguide plug, in order to pass on the light emitted by the optical semiconductor 9, or to guide toward the optical semiconductor 9 the light to be received by the optical semiconductor 9. The component 41 is schematically illustrated in FIG. 2a and is to be inserted into the guide member in a direction indicated by the arrow.

Contact surfaces 16 are formed between the optical semiconductor 9 and a mounting surface 15 on the bottom side 2 of the baseplate 3. This permits an effective transfer of the heat produced in the optical semiconductor 9 to the baseplate 3, such that the baseplate 3, which is preferably configured as a heat sink, can distribute and dissipate this transferred heat. The baseplate 3 is preferably formed from a metal, for example from copper, in order additionally to fulfill the function of protecting the optical semiconductor against interfering electromagnetic waves.

For a further semiconductor 17, as well, the baseplate 3 fulfils the function of a heat sink and/or of a protection configuration against interfering electromagnetic waves.

The optical semiconductor 9 is electrically connected to the conductor tracks 5 with the aid of bonds 18, which can be configured as wire bonds or tape bonds. Since the further semiconductor 17 is also connected to the conductor tracks 5 with the aid of further bonds 19, the further semiconductor 17 can be used to back up functions of the optical semiconductor 9 or to supplement new functions. Both the optical semiconductor 9 with the bonds 18 and the further semiconductor 17 with the bonds 19 are surrounded by a casting compound 20 and 21 respectively. The optical semiconductor 9 and the further semiconductor 17 are fixed with regard to the baseplate 3 and protected against external interference with the aid of the respective casting compound 20, 21.

The polyimide film 4 has cutouts 22, which are preferably of conical configuration. Soldering globules 23 are provided in the cutouts 22 such that the soldering globules are electrically connected to the conductor tracks 5. With the aid of the soldering globules 23 the transducer module 1 can be soldered on a circuit board 42 which has on its side averted from the transducer module 1 components, for example, passive components, which are required for the transducer module 1 to function.

In accordance with FIG. 2a, a silicon lens 24 can be constructed instead of the lens 12 on the optical semiconductor 9. The silicon lens 24 is preferably provided on the optical semiconductor 9 or a submount thereof so as to permit self-adjustment of the optical semiconductor 9 with regard to the passage 11.

FIG. 2b shows a detail of a transducer module in the case of which the optical semiconductor 9 is mounted on a bottom side 32 of a silicon lens submount 33. Contact is made with the optical semiconductor 9 via solder contacts and/or wire bonds. On a side 25 facing the baseplate, the guide member 14 has a projection 26 which is fitted into the passage 11 such that the guide member 14 can be self-adjusted with regard to the optical semiconductor 9.

In the production of a transducer module 1, the polyimide film 4 is firstly bonded with the conductor tracks 5 on the bottom side 2 of the baseplate 3. In this case, the conductor tracks 5 are provided on the side of the polyimide film 4 facing the baseplate 3. Thereafter, the optical semiconductor 9 and the further semiconductor 17 are inserted into the depressions 7 and 8, respectively. In a succeeding method step, the optical semiconductor 9 and the further semiconductor 17 are connected with the aid of wire bonds 18, 19 to bonding surfaces of the conductor tracks 5, the bonding surfaces being exposed by etching of the polyimide. The bonds 18 can be very short because of the small height distance of the surface 27 of the optical semiconductor 9 averted from the baseplate 3 and the plane in which the conductor tracks 5 are provided. This holds likewise for the further bonds 19 of the further semiconductor component 17.

The optical semiconductor 9 and the bonds 18 as well as the further semiconductor component 17 and the further bonds 19 are then filled with a respective casting compound 20, 21.

Finally, the transducer module 1 can be soldered on a circuit board with the aid of the soldering globules 23. The circuit board 42 is schematically shown in FIG. 2a.

Depending on whether a lens 12 or a silicon lens 24 is provided, a method step is to be provided for inserting the lens 12 in the passage 11.

FIG. 3 shows a further embodiment of a transducer module 1. In this case, a printed circuit board substrate 28 is provided on the bottom side 2 of the baseplate 3. Conductor tracks 30, preferably copper conductor tracks, are formed on a side 29 of the printed circuit board substrate 28 averted from the baseplate, and are electrically connected with the aid of the bonds 18 and the further bonds 19 to the optical semiconductor 9 or the further semiconductor 17.

The use of the printed circuit board substrate 28 has the advantage, in particular, that it is possible to form several layers which are situated one above another and in which conductor tracks run in each case, such that the packing density and integration density of the transducer module can be increased.

The optical semiconductor 9 is mounted in a cutout 31 in the printed circuit board substrate 28. The printed circuit board substrate 28 is formed, for example, from epoxy and glass.

I claim:

1. A transducer module for at least one of transmitting and receiving light, comprising:
a baseplate having a top side and a bottom side;
a printed circuit board substrate disposed on said bottom side of said baseplate;
conductor tracks provided on said printed circuit board substrate and being electrically insulated from said baseplate; and
at least one optical semiconductor electrically connected to said conductor tracks, said at least one optical semiconductor being positioned such that light is at least one of receivable and transmittable in a respective direction toward and away from said top side of said baseplate.

2. The transducer module according to claim 1, including an insulating adhesive for electrically insulating said conductor tracks from said baseplate.

3. The transducer module according to claim 1, wherein said printed circuit board substrate electrically insulates said conductor tracks from said baseplate.

4. The transducer module according to claim 1, wherein said printed circuit board substrate is formed from polyimide.

5. The transducer module according to claim 1, including bonds for connecting said at least one optical semiconductor to said conductor tracks.

6. The transducer module according to claim 5, wherein said bonds are wire bonds.

7. The transducer module according to claim 5, wherein said bonds are tape bonds.

8. The transducer module according to claim 5, including a casting compound, said casting compound at least partially surrounding said at least one optical semiconductor and said bonds.

9. The transducer module according to claim 1, wherein said baseplate is configured as a heat sink.

10. The transducer module according to claim 1, wherein said baseplate is a metal plate.

11. The transducer module according to claim 1, wherein said baseplate is a copper plate.

12. The transducer module according to claim 1, wherein said baseplate is formed with a passage for a light path extending at least partially through said passage during at least one of a light transmission and a light reception.

13. The transducer module according to claim 12, including a lens disposed in said passage and in the light path.

14. The transducer module according to claim 13, wherein said lens is a spherical lens.

15. The transducer module according to claim 13, wherein said lens is pressed into said passage.

16. The transducer module according to claim 13, including an adhesive, said adhesive bonding said lens in said passage.

17. The transducer module according to claim 16, wherein said adhesive is an index-matched, transparent adhesive.

18. The transducer module according to claim 13, wherein: said baseplate has a mounting surface on said bottom side;
said at least one optical semiconductor has a surface facing said mounting surface;
said at least one optical semiconductor is formed with an etched trench in said surface; and
said lens projects over said mounting surface such that said at least one optical semiconductor is positionable in a self-adjusting manner on said mounting surface through use of said etched trench.

19. The transducer module according to claim 13, wherein said lens is a silicon lens.

20. The transducer module according to claim 1, wherein:
said baseplate is formed with a depression on said bottom side; and
said at least one optical semiconductor is disposed in said depression.

21. The transducer module according to claim 5, including:
a semiconductor component disposed on said bottom side of said baseplate; and
further bonds connected to said semiconductor component and to said conductor tracks for electrically connecting said semiconductor component to said at least one optical semiconductor.

22. The transducer module according to claim 21, wherein said baseplate is formed with a depression at said bottom side for accommodating said semiconductor component.

23. The transducer module according to claim 1, including soldering globules electrically connected to said conductor tracks and to be soldered to a circuit board.

24. The transducer module according to claim 1, including a guide member disposed, above said at least one optical semiconductor, on said top side of said baseplate, said guide member being configured for holding one of a glass fiber cable and an optical waveguide plug.

25. The transducer module according to claim 24, wherein said guide member has a projection for a self-adjustment of said guide member with respect to the light propagating in the respective direction toward and away from said top side of said baseplate.

26. The transducer module according to claim 25, wherein:
said baseplate is formed with a passage for a light path extending at least partially through said passage during at least one of a light transmission and a light reception; and
said projection is at least partially disposed in said passage.

27. The transducer module according to claim 1, wherein said conductor tracks form contacts, and said at least one optical semiconductor is electrically connected to said conductor tracks via said contacts.

28. A method for producing a transducer module for at least one of transmitting and receiving light with at least one optical semiconductor, the method which comprises:
applying a contact layer, formed on a printed circuit board substrate, on a bottom side of a baseplate, the contact layer having conductor tracks electrically insulated from the baseplate;
forming at least one cutout in the contact layer;
positioning at least one optical semiconductor in the at least one cutout such that light is at least one of receivable and transmittable in a respective direction toward and away from a top side of the baseplate;
forming bond connections between the at least one optical semiconductor and the conductor tracks; and
casting the at least one optical semiconductor and the bond connections with a casting compound.

29. The method according to claim 28, which comprises:
forming a passage in the baseplate prior to the positioning step such that at least part of the light is at least one of transmittable and receivable through the passage; and
inserting a lens into the passage.

30. The method according to claim 28, which comprises:
forming a passage in the baseplate subsequent to the positioning step such that at least part of the light is at least one of transmittable and receivable through the passage; and
inserting a lens into the passage.
